(19) United States
(12) Patent Application Publication
(10) Pub. No.: US 2002/0140443 A1
(43) Pub. Date: Oct. 3, 2002

(54) Method and apparatus for inspecting conductive pattern

(76) Inventor: Kazuo Moriya, Ageo-shi (JP)

Correspondence Address: John F. Gulbin, Pitney, Hardin, Kipp & Szuch LLP, 685 Third Avenue, New York, NY, 10017-4024, US

(21) Appl. No.: 10/114,593

(22) Filed: Apr. 2, 2002

(30) Foreign Application Priority Data
Apr. 3, 2001 (JP) 2001-104738

(51) Int. Cl. G01R 31/305

(52) U.S. Cl. 324/751

(57) ABSTRACT

A pattern board (2) having a conductive pattern (2b) formed on an insulating substrate (2a) is irradiated with an electron beam (EB), and current flowing through a current flow path formed between the conductive pattern (2b) and the ground is detected by a current detector (10) while the irradiation position of the electron beam on the pattern board (2) is moved, thereby detecting the presence or absence of the conductive pattern (2b) or a conductor connected thereto at the electron beam irradiation position. The conductive pattern has a plurality of pattern portions which are linked to one another by a linking pattern portion, and current flowing through the linking pattern portion is detected while the irradiation position of the electron beam is moved along a path which successively traverses the tip portions of the plurality of pattern portions, thereby performing an inspection on the plurality of pattern portion.

### BACKGROUND OF THE INVENTION

1. Field of the Invention

The present invention belongs to a pattern inspecting technical field, and particularly relates to a method and apparatus for inspecting whether a conductive pattern is good or not. The method and apparatus for inspecting the conductive pattern of the present invention can be used to judge whether-a conductive pattern is good or not, for example in a process of forming the conductive pattern on an insulating substrate to form an electronic circuit board.

2. Description of the Related Art

In the semiconductor device manufacturing field, when an electronic circuit board on which electronic components such as semiconductor chips, etc. are to be mounted is manufactured, an inspection to check whether a conductive pattern for wires and other parts is correctly formed on an insulating board is carried out as one of inspection items to judge whether the circuit board is good or not. The inspection is performed by applying a voltage across two appropriate pattern portions of a conductive pattern which should not be conducted to each other and judging whether current flows between the two pattern portions or not.

According to the conductive pattern inspection as described above, in order to apply the voltage across the two pattern portions of the conductive pattern, a pair of probes connected to the positive and negative electrodes of a power source respectively are brought into contact with the two pattern portions to form a detection circuit and an ammeter is interposed in the detection circuit. If the two pattern portions are short-circuited, current flows in the detection circuit. Accordingly, when the current flow is detected by the ammeter, it is judged that some short-circuited portion exists, and the circuit board concerned is judged as a defective. On the other hand, if no current flows in the detection circuit, it is judged that there is no short-circuited portion between the two pattern portions concerned, and thus the circuit board concerned is judged as a non-defective product.

However, at the request of recent high-integration and miniaturization designs of semiconductor devices, enhancement of microstructure and density of the conductive patterns of circuit boards on which the semiconductor devices are to be mounted is promoted. Accordingly, when the conventional conductive pattern inspection method using contact type probes is carried out, it is gradually more difficult to perform the accurate contact between each of a pair of probes and each of neighboring pattern portions. When the probe contact is insufficient or the positional displacement between probe and the pattern portion is large, an accurate inspection for a conductive pattern cannot be performed.

Besides, in the conductive pattern inspection, there is a case where it is required not only to inspect the presence or absence of short-circuiting between neighboring patterns, but also to inspect whether each pattern portion is formed to have a desired shape within a permissible range. For this purpose, it is substantially impossible to use the method of bringing a pair of probes into contact with neighboring patterns. This is because although one probe can be brought into contact with a pattern portion, it is difficult to scan the other probe along the outline of the accurate shape for the pattern portion concerned while the probe is made to abut against a position which is slightly outwardly away from the outline, and this is substantially impossible for conductive patterns which are made finer in structure and have higher density.

Further, a method of inspecting whether a conductive pattern has a break-down portion is known as a simple inspection method for conductive patterns. That is, a voltage is applied across two portions of a conductive pattern which should be kept under a conduction state to check flow/non-flow of current, thereby judging whether a break-down occurs between the two portions. In most cases, such a break-down occurs at a microstructured tip portion of the pattern, however, it is extremely difficult for the conventional probe contact method to perform the accurate contact between the probe and the microstructured tip portion of the pattern, and thus it is impossible to perform an accurate judgment on the presence or absence of break-down.

Still further, a conductive pattern may have a portion which is not supported by a circuit board. In such a case, it is impossible to use the method of scanning the probe while keeping the contact between the probe and the pattern portion.

In order to overcome the above problem, there is proposed a method of optically picking up an image of the surface of a circuit board and comparing the image thus achieved with a predetermined conductive pattern to perform a non-contact inspection. However, the image thus achieved by this optical inspection method does not necessarily support to discriminate an electric conductor and a non-electric conductor from each other. For example, in such a case that there exists an electric conductor having a slope surface which does not clearly appear in an optical image or in such a case that a non-conductive dust adheres, an erroneous inspection result is achieved. In this case, a further electric complementary inspection is required.

### SUMMARY OF THE INVENTION

Therefore, an object of the present invention is to provide an inspection method and an inspection apparatus which can accurately and quickly perform a pattern inspection even when a conductive pattern is fine.

In order to attain the above object, according to the present invention, there is provided a method of inspecting a conductive pattern of a pattern board having an insulating substrate and the conductive pattern formed on the insulating substrate, wherein the pattern board is irradiated with an electron beam, and current flowing through the conductive pattern is detected while an irradiation position of the electron beam on the pattern board is moved to detect presence or absence of the conductive pattern or a conductor connected to the conductive pattern at the irradiation position of the electron beam.

In an aspect of the method of the present invention, the current flowing through the conductive pattern is detected at a current flow path formed between the conductive pattern and the ground.

In an aspect of the method of the present invention, the current the conductive pattern has a plurality of pattern portions connected to one another through a linking pattern portion, and the current flowing through the linking pattern portion is detected while the irradiation position of the electron beam is moved along a path which extends so as to successively traverse the tip portions of the plurality of pattern portions, the tip portions being away from connection portions of the plurality of pattern portions with the linking pattern portion, thereby performing an inspection on the plurality of pattern portions.

In another aspect of the method of the present invention, the conductive pattern comprises a plurality of pattern portions, and the current flowing through any one of the plurality of pattern portions is detected while the irradiation position of the electron beam is moved around the pattern portion, thereby performing an inspection on the pattern portion.

In still another aspect of the method of the present invention, permissible pattern data set on the basis of the shape of a reference conductive pattern is prepared in advance, the current flowing through the conductive pattern is detected while the irradiation position of the electron beam is moved over the overall pattern board, measurement pattern data are achieved as an assembly of the irradiation positions at which the current is detected, and protrusion data which are out of the permissible pattern data in the measurement pattern data are achieved, thereby performing an inspection.

Furthermore, in order to attain the above object, according to the present invention, there is provided an apparatus for inspecting a conductive pattern of a pattern board having an insulating substrate and the conductive pattern formed on the insulating substrate, comprising a pressure reduction chamber; holding means for the pattern board disposed in the pressure reduction chamber; an electron beam irradiating unit for irradiating therewith the pattern board held by the holding means; a current detector which is brought into contact with the conductive pattern of the pattern board held by the holding means; and driving means for moving an irradiation position of the electron beam on the pattern board.

In an aspect of the apparatus of the present invention, pattern board feeding means for feeding the pattern board to the holding means and receiving the pattern board from the holding means is disposed in the pressure reduction chamber.

In an aspect of the apparatus of the present invention, the driving means comprises deflecting means for deflecting the electron beam of the electron beam irradiating unit.

In another aspect of the apparatus of the present invention, the current detector has a current flow path formed between a contact portion with the conductive pattern and the ground, and an ammeter disposed in the current flow path.

In still another aspect of the apparatus of the present invention, the apparatus further comprises storing means for storing a signal of current detection at the current detector as measurement pattern data in association with a signal of the irradiation position of the electron beam set by the driving means.

In still another aspect of the apparatus of the present invention, the apparatus further comprises an operation processor for comparing the measurement pattern data with permissible pattern data which are stored in the storing means and set on the basis of the shape of a reference conductive pattern.

According to the present invention, the inspection of the conductive pattern is carried out by detecting the presence or absence of current flowing through the conductive pattern while the spot scanning of the electron beam is carried out on the pattern board, so that the pattern inspection can be accurately and quickly performed even when the conductive pattern is fine.

### BRIEF DESCRIPTION OF THE DRAWINGS

FIG. 1 is a schematic diagram showing a method and apparatus for inspecting a conductive pattern according to the present invention;

FIG. 2 is a schematic diagram showing a specific example of an inspection of a conductive pattern according to the present invention;

FIGS. 3A, 3B and 3C schematically show a specific example of an inspection of a conductive pattern according to the present invention;

FIG. 4 is a schematic diagram showing a pattern board to be inspected by the method and apparatus for inspecting conductive pattern according to the present invention; and

FIG. 5 is a schematic diagram showing a pattern board to be inspected by the method and apparatus for inspecting conductive pattern according to the present invention.

### DETAILED DESCRIPTION OF THE PREFERRED EMBODIMENTS

Preferred embodiments according to the present invention will be described hereunder with reference to the accompanying drawings.

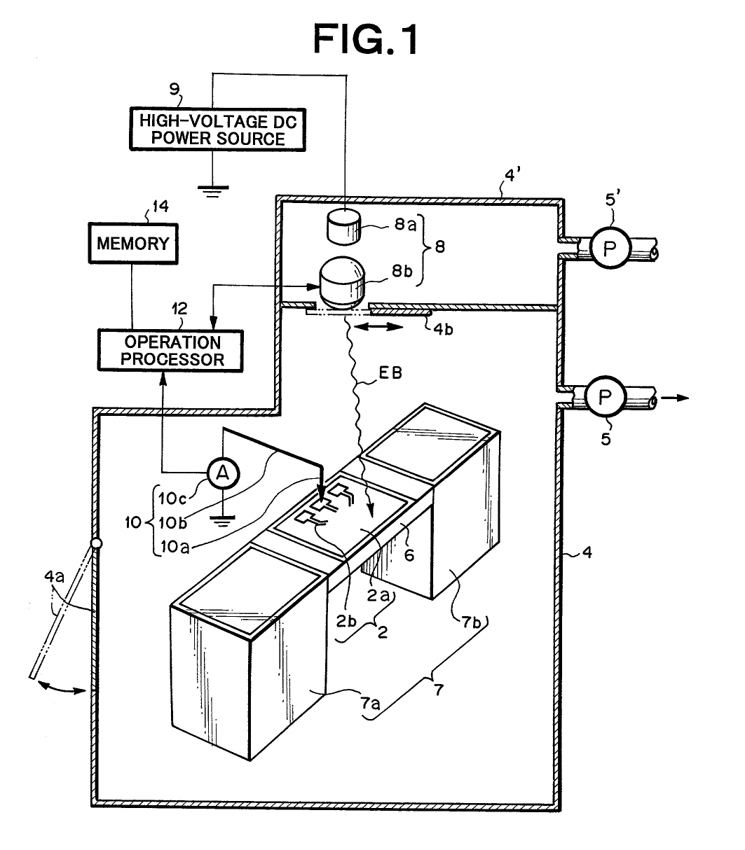

FIG. 1 is a schematic diagram showing an embodiment of the method and apparatus for inspecting conductive pattern according to the present invention.

A pattern board 2 to be inspected has a conductive pattern 2b formed on the surface of an insulating substrate 2a. The inspecting apparatus of this embodiment has a pressure reduction chamber 4. The inner space of the pressure reduction chamber 4 is reduced in pressure by pressure reducing means such as a vacuum pump 5, and kept to such a vacuum degree (for example, 10 Pa) that electron beam irradiation can be performed. In the pressure reduction chamber 4 are disposed holding means 6 for holding the pattern board 2 so that the pattern board 2 is located at a predetermined position and kept to a predetermined posture for the inspection, and also pattern board feeding means 7 for feeding the pattern board 2. The pattern board feeding means 7 comprises a supply portion 7a for supplying a pattern board 2 before inspection to the holding means 6, and a receiving portion 7b for receiving an inspected pattern board 2 from the holding means 6. The supply portion 7a and the receiving portion 7b are designed so that many pattern boards 2 can be accommodated therein and successively taken out/received one by one when the inspection is carried out.

The pressure reduction chamber 4 is equipped with a door 4a. The door 4a is opened when the pattern board 2 before the inspection is fed from the outside of the pressure reduction chamber 4 into the supply portion 7a of the pattern board feeding means 7 in the pressure reduction chamber 4 and when the pattern board 2 after the inspection is fed from the receiving portion 7b of the pattern board feeding means 7 in the pressure reduction chamber 4 to the outside of the pressure reduction chamber 4.

The inspecting apparatus is equipped with an electron beam irradiating unit 8 for irradiating with the electron beam EB the pattern board 2 held by the holding means 6 to form an electron beam spot on the pattern board 2. The electron beam irradiating unit 8 is equipped with an electron gun 8a for emitting an electron beam and deflecting means 8b for deflecting the electron beam emitted downwardly from the electron gun 8a to form the electron beam spot having a diameter of about 1 μm or less to a desired position on the overall surface of the pattern board 2. That is, the deflecting means 8b serves as driving means for moving the electron beam irradiation position on the pattern board 2.

The electron beam irradiation unit 8 is disposed in a pressure reduction chamber 4′. The inner space of the pressure reduction chamber 4′ is reduced in pressure by a vacuum pump 5′ to be kept under such a vacuum degree (for example, 10 Pa) that the electron beam irradiation can be performed. The pressure reduction chamber 4′ may be kept under a vacuum degree higher than that of the pressure reduction chamber 4. The pressure reduction chamber 4′ intercommunicates with the pressure reduction chamber 4 only at the position through which the electron beam EB passes.

A door 4b is provided at the position through which the electron beam EB passes, and the door 4b is closed as occasion demands (for example, when the pattern board 2 before inspection is fed from the outside of the pressure reduced chamber 4 to the supply portion 7a of the feeding means 7 in the pressure reduction chamber 4 or when the pattern board after inspection is fed from the receiving portion 7b of the feeding means 7 in the pressure reduction chamber 4 to the outside of the pressure reduction chamber 4). Power is supplied from a high-voltage DC power source 9 to the electron gun 8a. For example, the same type as used in a scanning electron microscope may be used as the electron beam irradiation unit 8 as described above.

The inspecting apparatus has a current detector 10 which is brought into contact with the conductive pattern 2b of the pattern board 2 held by the holding means 6. The current detector 10 has a current flow path or passage 10b formed between the contact portion 10a thereof with the conductive pattern 2b and the ground, and further has an ammeter 10c interposed in the current flow passage 10b.

The inspecting apparatus is equipped with an operation processor 12 and a memory 14. A current detection signal is input from the current detector 10 to the operation processor 12, and also a signal indicating the electron beam irradiation position is input from the deflecting means 8b to the operation processor 12. These two signals are stored as measurement pattern data in a memory 14 while associated with each other. In the memory 14 are stored data of a reference conductive pattern such as design values, etc. and data of a permissible pattern set on the basis of the reference conductive pattern. The permissible pattern may be formed by adding a permissible error portion to the outline of the reference pattern.

In the operation processor 12, the measurement pattern data are compared with the permissible pattern data stored in the memory 14 to carry out an inspection on the conductive pattern 2b.

In this embodiment, the inspection is carried out as follows. That is, spot irradiation with electron beam EB emitted from the electron beam irradiating unit 8 is carried out on the pattern board 2, and the current flowing through the conductive pattern 2b is detected by the ammeter 10c of the current detector 10 while the electron beam irradiation position on the pattern board 2 is scanned by the deflecting means 8b, thereby detecting the conductive pattern 2b at the electron beam irradiating position or a conductor electrically connected to the conductive pattern 2b (for example, a bridge or the like formed at an out-of-schedule portion so as to connect neighboring pattern portions constituting a prescribed conductive pattern to each other when the pattern is formed). The scanning of the electron beam irradiation position on the pattern board 2 by the deflecting means 8b may be performed in a desired manner in response to an instruction from the operation processor 12 (in this case, the signal of the electron beam irradiation position is achieved on the basis of the instruction signal emitted from the operation processor 12, and thus the signal of the electron beam irradiation position is unnecessary to be input from the deflecting means 8b to the operation processor 12).

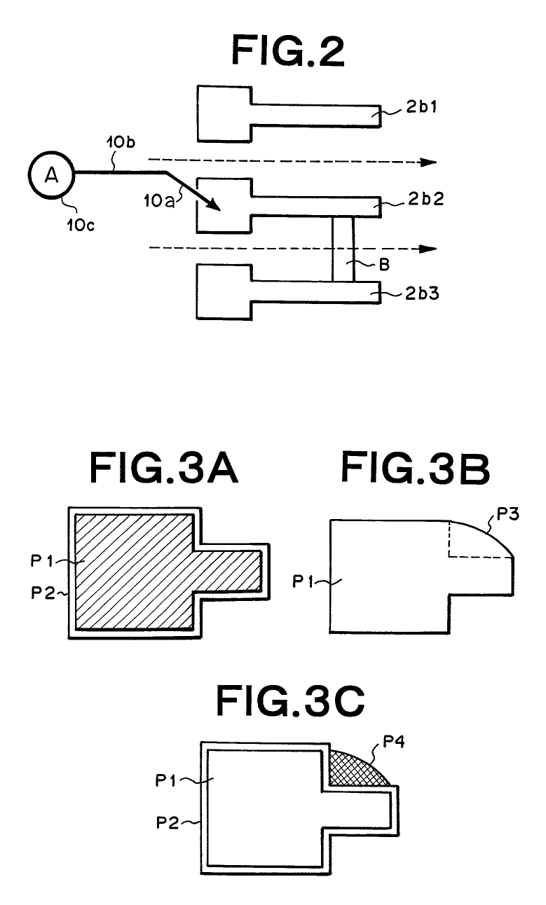

FIG. 2 is a schematic diagram showing a specific example of the inspection.

Here, it is assumed that the conductive pattern 2b comprises a plurality of pattern portions 2b1, 2b2, 2b3, etc. For example, the contact portion 10a is brought into contact with the pattern portion 2b2, and the electron beam irradiation position is moved as indicated by broken lines around the pattern portion 2b2 to be detected while the current flowing through the current flow path or passage 10b is detected by the ammeter 10c. The scanning path is located in an area out of the permissible pattern. The scanning may be carried out along a path which is closed so as to surround the pattern portion 2b2 concerned. Accordingly, when a bridge B exists between the pattern portions 2b2 and 2b3 as shown in FIG. 2, a current detection signal occurs at the time when the electron beam is scanned at the bridge position, whereby it can be immediately judged by the operation processor 12 that some trouble occurs at the position associated with the current detection.

FIGS. 3A to 3C show a specific example of the inspection which is different from that of FIG. 2.

Data of a permissible pattern P2 set on the basis of the shape of a reference conductive pattern P1 are prepared in advance as shown in FIG. 3A. The current detection is carried out by the current detector 10 while the irradiation position of the electron beam is moved at a sufficient scanning density over the overall pattern board 2, and data of a measurement pattern P3 as shown in FIG. 3B are achieved as an assembly of the irradiation positions at which the current is detected. Further, data of a protrusion pattern P4 out of the data portion belonging to the permissible pattern data in the measurement pattern data are determined as shown in FIG. 3C. Accordingly, the operation processor 12 can judge that some trouble occurs in the area corresponding to the protrusion pattern P4.

In the embodiments of the present invention as described above, only the contact portion 10a of the current detector 10 is brought into mechanical contact with the conductive pattern 2b, and the electron beam spot serves as another probe. The diameter of the electron beam spot is sufficiently small, so that the inspection can be performed on a conductive pattern with sufficient resolution even when the conductive pattern is made fine (particularly, as a tip portion of a tapered pattern or the like).

The measurement pattern data are associated with the pattern of an electric conductor which is clearly discriminated from a non-electric conductor, and thus the inspection can be performed sufficiently accurately and quickly by only the above-described image processing on the basis of the measurement pattern data.

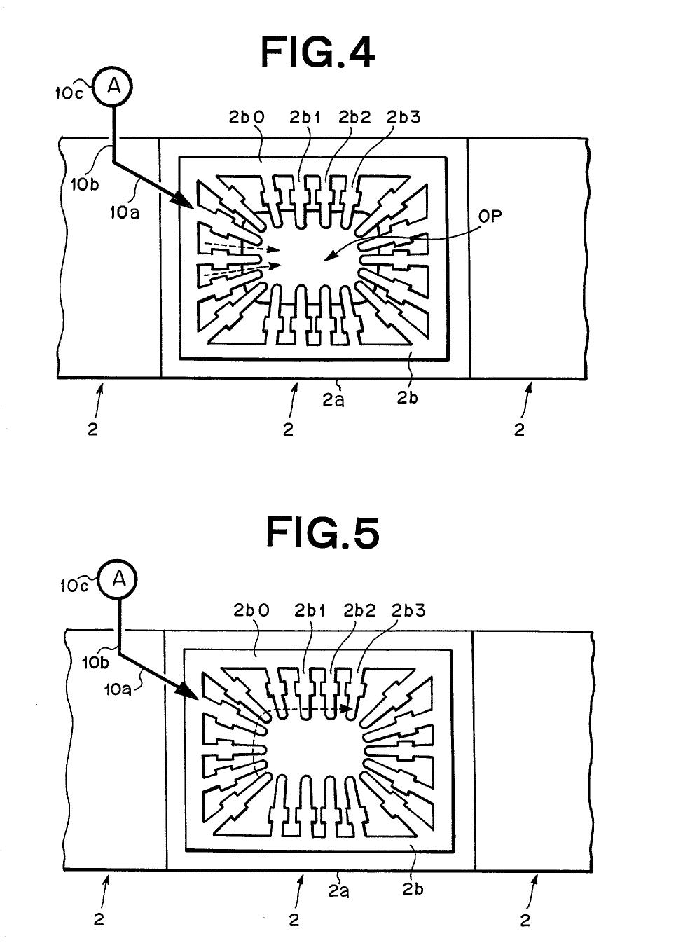

Further, the present invention may be applied to a case where a plurality of conductive patterns are integrally and continuously formed. FIG. 4 shows an embodiment of this case. In this embodiment, an elongated flexible insulating film such as polyimide film or the like is used as the insulating substrate 2a, and a conductive pattern 2b is repetitively formed on the insulating substrate 2a, thereby forming an elongated board on which a series of many pattern boards 2 are formed. The conductive pattern 2b of each pattern board 2 is designed such that many pattern portions 2b1, 2b2, 2b3, . . . are linked to one another by an outer peripheral linking pattern portion 2b0 as shown in FIG. 4. In the case of this embodiment, an extension reel and a take-up reel which serve as the supply portion 7a and the receiving portion 7b, respectively, of the feeding means 7 shown in FIG. 1 may be used.

In this embodiment, the contact portion 10a of the current detector 10 is brought into contact with the conductive pattern 2b, and the electron beam spot is scanned as indicated by the broken lines between neighboring pattern portions. If there exists any short-circuited portion between the neighboring pattern portions, the short-circuited portion is detected. Recently, in a circuit board on which a semiconductor device is mounted, particularly the tip portions at the inner sides of the pattern portions 2b1, 2b2, 2b3 . . . are designed to be finer in microstructure and higher in density. According to this embodiment, the irradiation spot diameter of the electron beam EB can be set to a sufficiently smaller value than the width of the conductive pattern or the interval between the neighboring conductive patterns, so that the inspection can be performed with excellent precision.

In this embodiment, the tip portions of the respective pattern portions 2b1, 2b2, 2b3, . . . may be designed not to be supported by the insulating substrate 2a. That is, as shown in FIG. 4, a central opening OP may be formed in the insulating substrate 2a, and the tip portions of the pattern portions 2b1, 2b2, 2b3, . . . may be designed to extend into the central opening OP (a semiconductor chip will be disposed in the central opening OP in a subsequent step of the semiconductor manufacturing process). In such a case, by the conventional probe method, the probe cannot be brought into stable contact with the tip portion of the pattern, and thus no inspection cannot be performed. However, the inspection can be performed by the method of the above embodiment of the present invention.

Further, as shown in FIG. 5, the contact portion 10a of the current detector is brought into contact with the outer peripheral linking pattern portion 2b0, and the current detection is performed by the current detector 10 while the irradiation position of the electron beam EB is moved as indicated by the broken lines so as to traverse the tip portions of the pattern portions 2b1, 2b2, 2b3, . . . , whereby the presence or absence of some break-down of each pattern portion can be quickly detected. That is, when current is detected during the electron beam irradiation to the tip portion of each pattern portion (the tip portion of the reference conductive pattern such as the design values, etc.), it is judged that there is no break-down in the pattern portion. On the other hand, when no current is detected, a break-down is judged as to the pattern portion.

In this embodiment, as in the case of the embodiment shown in FIG. 4, the inspection can be performed with excellent precision on a pattern having a tip portion having a finer microstructure and high density which cannot be inspected by the conventional probe method.

As described above, according to the present invention, the irradiation position of the electron beam EB is scanned through a desired path or passage, and the presence or absence of a lack portion of the conductive pattern or the presence or absence of addition of an undesired conductive portion can be surely inspected in short time.

What is claimed is:

1. A method of inspecting a conductive pattern of a pattern board having an insulating substrate and the conductive pattern formed on the insulating substrate, characterized in that the pattern board is irradiated with an electron beam, and current flowing through the conductive pattern is detected while an irradiation position of the electron beam on the pattern board is moved to detect presence or absence of the conductive pattern or a conductor connected to the conductive pattern at the irradiation position of the electron beam.

2. The method as claimed in claim 1, wherein the current flowing through the conductive pattern is detected at a current flow path formed between the conductive pattern and the ground.

3. The method as claimed in any one of claims 1 and 2, wherein the conductive pattern has a plurality of pattern portions connected to one another through a linking pattern portion, and the current flowing through the linking pattern portion is detected while the irradiation position of the electron beam is moved along a path which extends so as to successively traverse the tip portions of the plurality of pattern portions, the tip portions being away from connection portions of the plurality of pattern portions with the linking pattern portion, thereby performing an inspection on the plurality of pattern portions.

4. The method as claimed in any one of claims 1 and 2, wherein the conductive pattern comprises a plurality of pattern portions, and the current flowing through any one of the plurality of pattern portions is detected while the irradiation position of the electron beam is moved around the pattern portion, thereby performing an inspection on the pattern portion.

5. The method as claimed in any one of claims 1 and 2, wherein permissible pattern data set on the basis of the shape of a reference conductive pattern is prepared in advance, the current flowing through the conductive pattern is detected while the irradiation position of the electron beam is moved over the overall pattern board, measurement pattern data are achieved as an assembly of the irradiation positions at which the current is detected, and protrusion data which are out of the permissible pattern data in the measurement pattern data are achieved, thereby performing an inspection.

6. An apparatus for inspecting a conductive pattern of a pattern board having an insulating substrate and the conductive pattern formed on the insulating substrate, comprising:
a pressure reduction chamber;
holding means for the pattern board disposed in said pressure reduction chamber;
an electron beam irradiating unit for irradiating therewith the pattern board held by said holding means;
a current detector which is brought into contact with the conductive pattern of the pattern board held by said holding means; and
driving means for moving an irradiation position of the electron beam on the pattern board.

7. The apparatus as claimed in claim 6, wherein pattern board feeding means for feeding the pattern board to said holding means and receiving the pattern board from said holding means is disposed in said pressure reduction chamber.

8. The apparatus as claimed in any one of claims 6 and 7, wherein said driving means comprises deflecting means for deflecting the electron beam of said electron beam irradiating unit.

9. The apparatus as claimed in any one of claims 6 to 7, wherein said current detector has a current flow path formed between a contact portion with the conductive pattern and the ground, and an ammeter disposed in said current flow path.

10. The apparatus as claimed in any one of claims 6 to 7, further comprising storing means for storing a signal of current detection at said current detector as measurement pattern data in association with a signal of the irradiation position of the electron beam set by said driving means.

11. The apparatus as claimed in claim 10, further comprising an operation processor for comparing the measurement pattern data with permissible pattern data which are stored in said storing means and set on the basis of the shape of a reference conductive pattern.
